(19) United States
(12) Patent Application Publication
(10) Pub. No.: US 2009/0323273 A1
(43) Pub. Date: Dec. 31, 2009

(54) SUPPORT DEVICE AND ELECTRONIC DEVICE USING SAME

(75) Inventor: MAO-SHENG HUANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/485,935

(22) Filed: Jun. 17, 2009

(30) Foreign Application Priority Data
Jun. 30, 2008 (CN) 200810302441.1

(51) Int. Cl. G06F 1/20; H05K 7/00

(52) U.S. Cl. 361/679.46; 361/748

(57) ABSTRACT

A support device used to support a circuit board includes a substrate, a plurality of protrusions, and a plurality of electrical-conductive pads. The protrusions are perpendicularly extending from a surface of the substrate and arranged as a matrix and each of the protrusions defines a threaded hole therein. The electrical-conductive pads are mounted on the substrate around the corresponding protrusions and grounding the circuit board.

### BACKGROUND

1. Technical Field

The disclosure relates to a support device, and more particularly, to a support device used in personal computers.

2. Description of Related Art

A central processing unit (CPU) is mounted on a motherboard in a computer for processing data. When the computer is operated, heat produced by the CPU must be dispersed external to the computer. If heat builds up internal to the computer, this creates excessively high temperature which will lower the performance of the CPU and/or even permanently damage the CPU. Various cooling devices are provided in the computer for dissipating heat. Traditional cooling devices have a number of fins stacked together to dissipate heat. The stacked fins of the cooling devices are mounted on a main board on which the CPU is mounted. Therefore the full weight of the cooling devices and the CPU is directly supported by the main board, and as a result the main board is prone to damages due to the weight.

Therefore, it is desirable to provide a support device and an electronic device using the same to support a cooling device used in a personal computer to eliminate or at least alleviate the above problems.

### BRIEF DESCRIPTION OF THE DRAWINGS

FIG. 1 is an isometric, exploded view of an electronic device according to an exemplary embodiment.

FIG. 2 is an assembly view of the electronic device of FIG. 1.

FIG. 3 is a section view of the electronic device of FIG. 2 along the line II-II.

### DETAILED DESCRIPTION

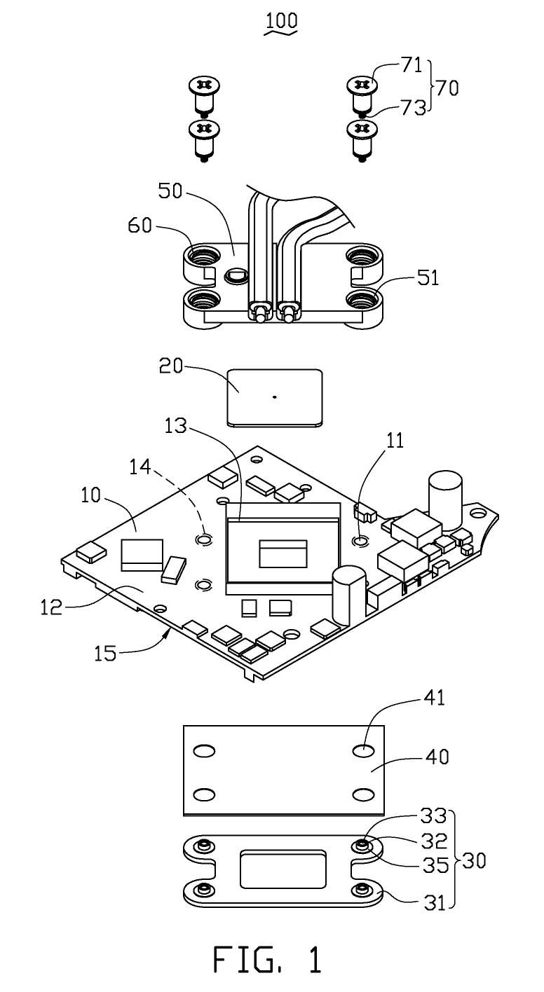

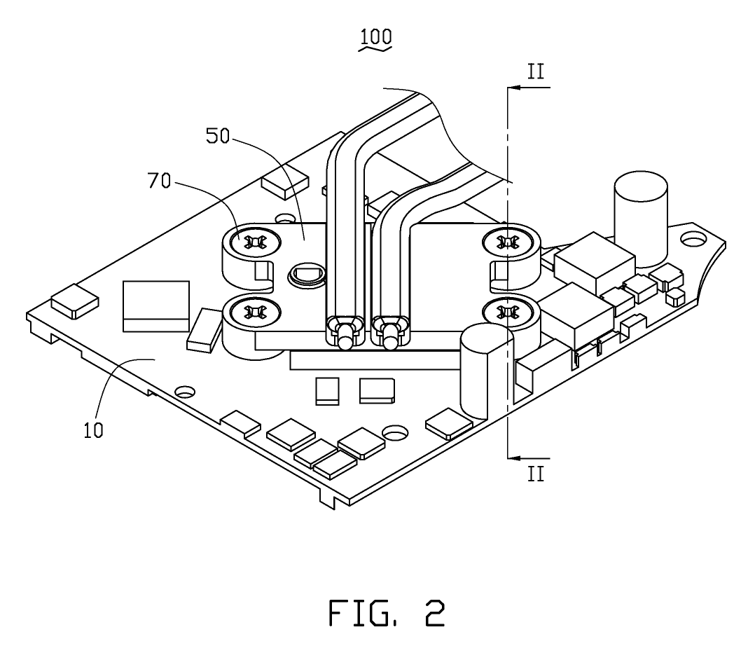

Referring to FIGS. 1-2, an eletronic device 100 according to an embodiment of the present invention, includes a circuit board 10, a CPU 20, a support device 30, an insulated pad 40, a colling device 50, a number of elastic members 60 and a number of fastensing member 70. The CPU 20 is mounted on the circuit board 10. The support device 30 is configured to support the circuit board 10. The insulated pad 40 is positioned between the circuit board 10 and the support device 30. The cooling device 50 is mounted on the circuit board 10. The fastensing members 70 pass through the corresponding elastic members 60 to connect to the cooling device 50, the circuit board 10, and the support device 30 in that order with the support device 30 in bottom.

The circuit board 10 includes an upper surface 12 and a lower surface 15 at an opposite side of the circuit board 10. The circuit board 10 includes a number of conductive tracks (not shown) and a number of electronic members (not labeled) attached on the upper surface 12. The circuit board 10 defines a number of through holes 11 through the upper and lower surfaces 12, 15, and a receiving space 13 formed in the upper surface 12 for receiving the CPU 20 therein. The circuit board 10 includes a number of grounding rings 14 formed on the lower surface 15 around the corresponding through holes 11.

The CPU 20 is received in the receiving space 13 of the circuit board 10. Alternatively, the CPU 20 can be substituted by other data processing modules.

The support device 30 is made of electrical-conductive material, and includes a substrate 31, a number of protrusions 32, and a number of conductive pads 35. The protrusions 32 perpendicularly extend away from a surface of the substrate 31 and are arranged as a matrix corresponding to the through holes 11 of the circuit board 10. Each of the protrusions 32 defines a threaded hole 33 therein. The conductive pads 35 are mounted on the substrate 31 around the corresponding protrusions 32. The protrusions 32 are fitted into the through holes 11 of the circuit board 10. The conductive pads 35 and the grounding ring 14 of the circuit board 10 are arranged to be connected to each other for grounding the circuit board 10 when the protrusions 32 are fitted into the through holes 11. Therefore, the electronic members and the CPU 20 mounted on the circuit board 10 are immunized from static electricity.

The insulated pad 40 is positioned between the support device 30 and the circuit board 10 for protecting the support device 30 from electrically contacting the lead pins (not shown) of the circuit board 10. The insulated pad 40 defines a number of orifices 41 running through itself for the corresponding protrusions 32 passing through to fit into the corresponding through holes 11 of the circuit board 10.

The cooling device 50 is attached on the circuit board 10 and contacts the CPU 20 for dispersing the heat produced by the CPU 20 and protecting the CPU 20 from over heating. The cooling device 50 defines a number of step holes 51 thereon for engaging with the corresponding fastening members 70 to fix the cooling device 50 on the support device 30.

Each of the elastic members 60 is a spring and received in the corresponding step hole 51 of the cooling device 50.

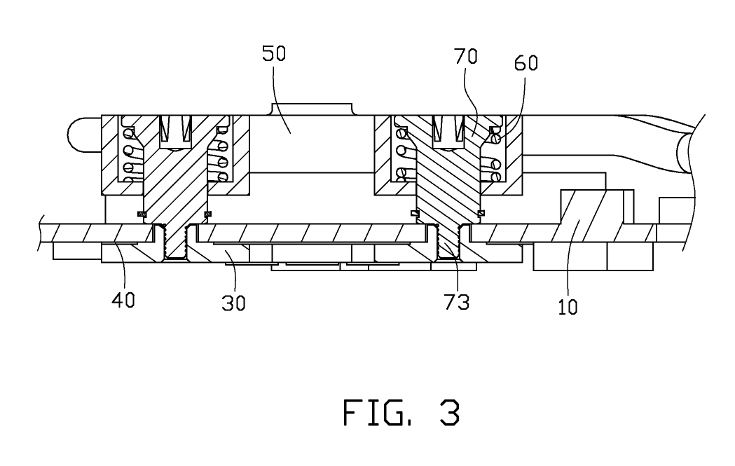

Further referring to FIG. 3, each of the fastening members 70 includes a cap nut 71 and a bolt 73. The cap nuts 71 are received in the corresponding step holes 51 of the cooling device 50. The bolt 73 are mated in the threaded holes 33 of the protrusions 32 to fix the cooling device 50 and the circuit board 10 on the support device 30 by passing the bolt 73 through the step holes 51 of the cooling device 50, the through holes 11 of the circuit board 10, and the orifices 41 of the insulated pad 40 in turn correspondingly. The elastic members 60 received in the step holes 51 of the cooling device 50 are compressed by the fastening members 70 so that the cooling device 50 is forced by the compressed elastic members 60 to tightly contact to the CPU 20 to cool the CPU 20 effectively.

In the present invention, the support device 30 is employed to support the cooling device 50 thereby releasing the circuit board 10 from being directly weighed down by the cooling device 50. Therefore, the circuit board 10 has a longer service life.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A support device used to support a circuit board comprising:
a substrate;
a plurality of protrusions extending upward from a surface of the substrate;
a plurality of threaded holes defined in the corresponding protrusions, and
a plurality of electrical-conductive pads mounted on the substrate around the corresponding protrusions for grounding the circuit board.

2. An electronic device comprising:
a circuit board;
a processing module mounted on the circuit board;
a cooling device mounted on the circuit board in contact with the processing module;
a support device configured to support the circuit board;
an insulated pad positioned between the circuit board and the support device; and
a plurality of fastening members configured to fix the cooling device and the circuit board on the support device.

3. The electronic device as claimed in claim 2, wherein the circuit board comprises an upper surface, an opposite lower surface, and a plurality of through holes running through the upper surface and the lower surface thereof.

4. The electronic device as claimed in claim 3, wherein the circuit board further comprises a plurality of grounding rings formed on the lower surface of the circuit board around the corresponding through holes.

5. The electronic device as claimed in claim 4, wherein the circuit board defines a receiving space on the upper surface for receiving the processing module therein.

6. The electronic device as claimed in claim 5, wherein the support device is made of electrical-conductive material.

7. The electronic device as claimed in claim 6, wherein the support device comprises a plurality of conductive pads passing through the insulated pad and electrically contacting to the grounding rings of the circuit board for grounding the circuit board.

8. The electronic device as claimed in claim 7, wherein the support device further comprises a substrate and a plurality of protrusions perpendicularly extending from a surface of the substrate and the conductive pads are mounted on the substrate around the corresponding protrusions.

9. The electronic device as claimed in claim 8, wherein the protrusions of the support device are arranged as a matrix corresponding to the through holes of the circuit board.

10. The electronic device as claimed in claim 9, wherein the cooling device defines a plurality of step holes therein; each of the protrusions defines a threaded holes therein; and the fastening members pass the step holes and the through holes and thread in the threaded holes of the protrusions to fix the cooling device and the circuit board on the support device.

11. The electronic device as claimed in claim 10, further comprising a plurality of elastic members received in the corresponding step holes of the cooling device and compressed by the fastening members.

12. The electronic device as claimed in claim 11, wherein the elastic members are springs.
